(19) United States
(12) Patent Application Publication
(10) Pub. No.: US 2013/0181098 A1
(43) Pub. Date: Jul. 18, 2013

(54) PORTABLE SUPPORTING MEMBER

(71) Applicant: CHIA-CHING LIN, TAIPEI CITY (TW)

(72) Inventor: CHIA-CHING LIN, TAIPEI CITY (TW)

(21) Appl. No.: 13/348,791

(22) Filed: Jan. 12, 2012

(51) Int. Cl. H05K 7/00

(52) U.S. Cl. 248/122.1

(57) ABSTRACT

A supporting stand connecting to a connection port of an electronic device includes a tubular casing and a positioning portion. The tubular casing has a receiving compartment and a first guiding hole communicating to the receiving compartment. The positioning portion is protruded from an outer surface of the tubular casing and the positioning portion is inserted into the connection port of the electronic device. The portable supporting member can be used to support the electronic device in a portrait orientation or a landscape orientation.

### BACKGROUND OF THE INVENTION

1. Field of the Invention

The present invention relates to a portable supporting member. In particular, the present invention relates to a portable supporting member for assembling to a connection port of the electronic device.

2. Description of Related Art

With developments of technology, the sizes of electronic devices, such as smart phones shrink and become smaller. A user may hold the electronic device in one hand and be able to control the touch-screen by the other hand. After touching the screen, the fingerprint oils, smudging or other items are deposited on the panel of the touch-screen. On the other hand, the use of the stylus may prevent the deposition of the fingerprint oils.

The stylus is usually used to aid to control the touch-screen. However, some electronic devices have no receiving compartment to receive the stylus; therefore, losing the stylus or misplacing the stylus has become almost commonplace.

Therefore, what is needed is a system for preventing the loss and the misplacing of a stylus of an electronic device.

### SUMMARY OF THE INVENTION

The instant disclosure is providing a portable supporting member. The portable supporting member of the instant disclosure is provided for supporting an electronic device in a portrait orientation or a landscape orientation. That means the portable supporting member of the instant disclosure may meet the requirement of user.

The instant disclosure provides a portable supporting member connecting to a connection port of an electronic device. The portable supporting member includes a supporting stand and a rod body selectively assembled with the supporting stand in a first and a second positions. The supporting stand includes a tubular casing and a positioning portion. The tubular casing has a receiving compartment and a first guiding hole communicating to the receiving compartment. The positioning portion is protruded from an outer surface of the tubular casing and the positioning portion is inserted into the connection port of the electronic device. The rod body is assembled to the first guiding hole in the first position and the rod body is penetrated through and received in the tubular casing in the second position.

The instant disclosure further provides a supporting stand connecting to a connection port of an electronic device. The supporting stand includes a tubular casing and a positioning portion. The tubular casing has a receiving compartment and a first guiding hole communicating to the receiving compartment. The positioning portion is protruded from an outer surface of the tubular casing and the positioning portion is inserted into the connection port of the electronic device.

By assembling the rod body with the supporting stand to form a portable supporting member, the portable supporting member may be used to support the electronic device in a portrait orientation or a landscape orientation. Furthermore, the rod body is assembled to the first guiding hole in the first position and is penetrated through and received in the tubular casing in the second position.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

FIG. 1 shows an exploded view of the portable supporting member with the device of the first embodiment of the instant disclosure.

FIG. 2 shows another exploded view of the portable supporting member with the device of the first embodiment of the instant disclosure.

FIG. 3 shows a perspective view of the portable supporting member with the device of the first embodiment of the instant disclosure.

FIG. 4 shows the instant portable supporting member with the device standing in a portrait orientation on the table.

FIG. 5 shows the instant portable supporting member with the device standing in a landscape orientation.

FIG. 6 shows the rod body inserting in the receiving compartment of the tubular casing according to the instant disclosure.

FIG. 6A shows the partial cross-sectional view of FIG. 6.

FIG. 7 shows the exploded view of the portable supporting member with the device of the second embodiment of the instant disclosure.

FIG. 8 shows the instant portable supporting member with the device standing in a portrait orientation on the table according to the second embodiment of the instant disclosure.

FIG. 9 shows a perspective view of the portable supporting member with the device of the second embodiment of the instant disclosure.

FIG. 10 shows the instant portable supporting member with the device standing in a landscape orientation according to the second embodiment of the instant disclosure.

### DETAILED DESCRIPTION OF THE PREFERRED EMBODIMENTS

The first embodiment is described hereinafter.

The present invention is not restricted by the quantity of the element described hereinafter.

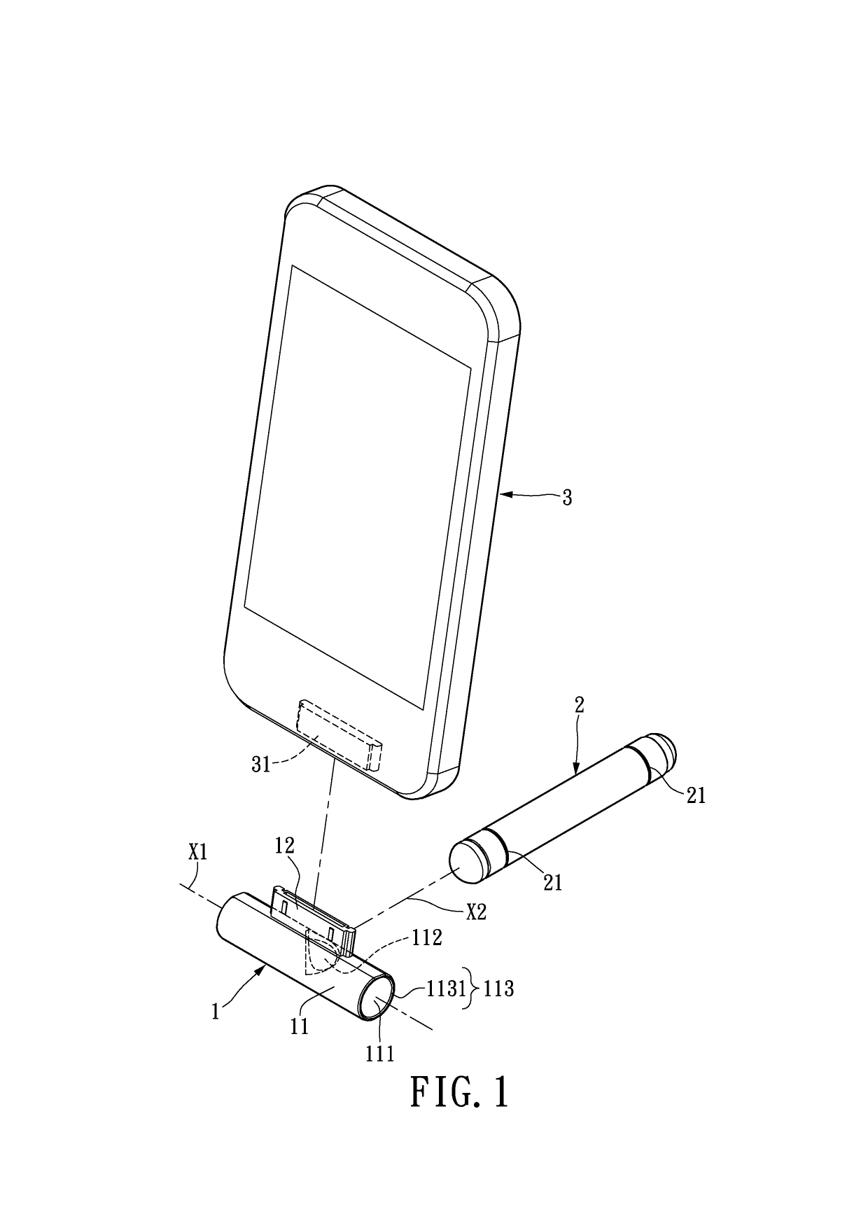

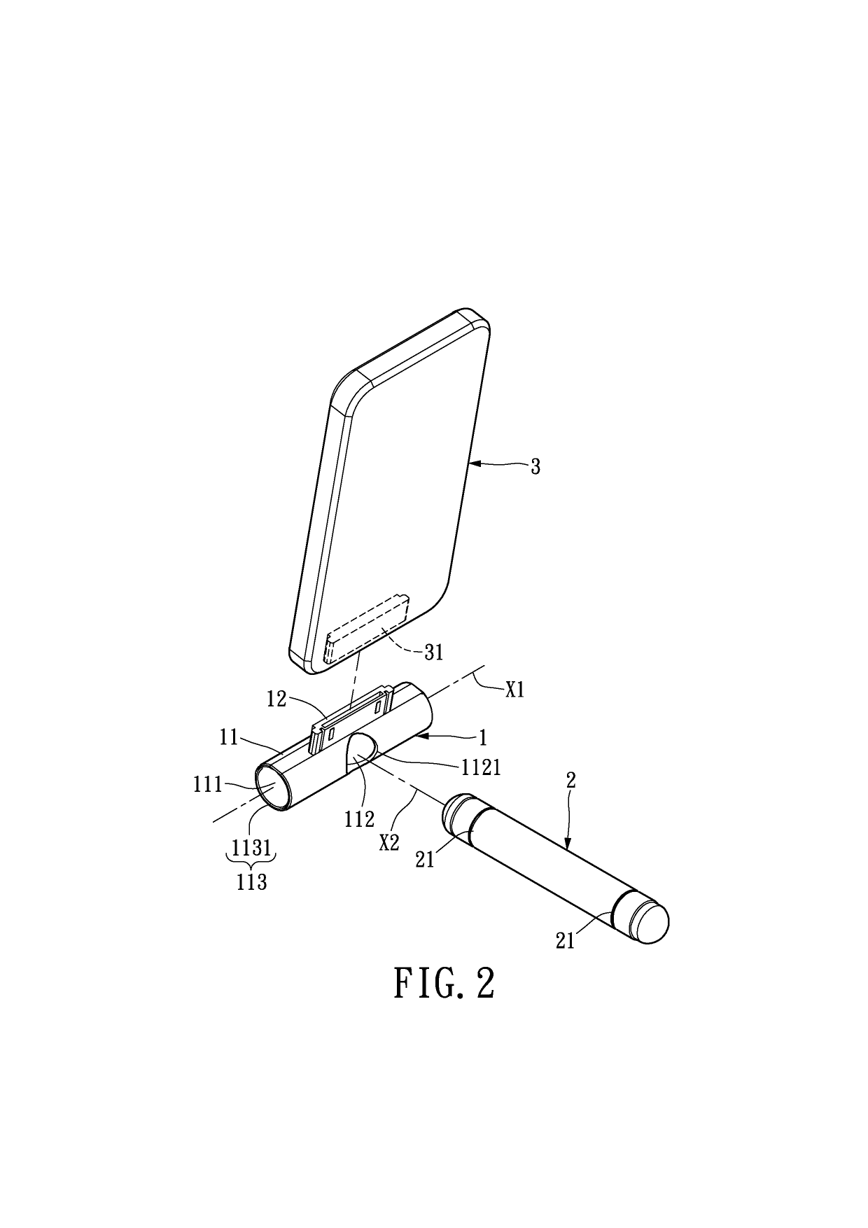

Please refer to FIGS. 1 and 2; the instant disclosure provides a portable supporting member to assemble an electronic device 3 (e.g., a smart phone) thereon. As shown, a connection port 31 of the electronic device 3 is connected to the portable supporting member. In detail, the portable supporting member includes a supporting stand 1 and a rod body 2.

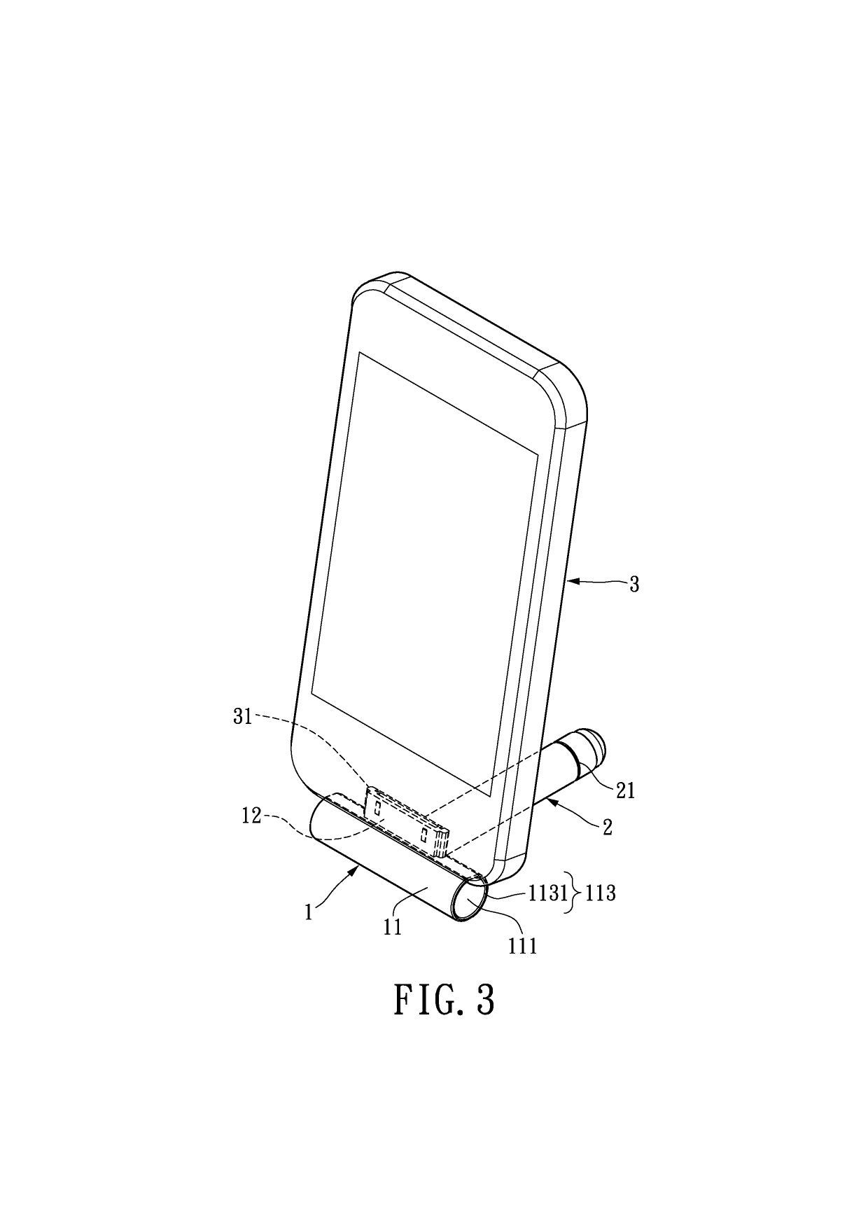

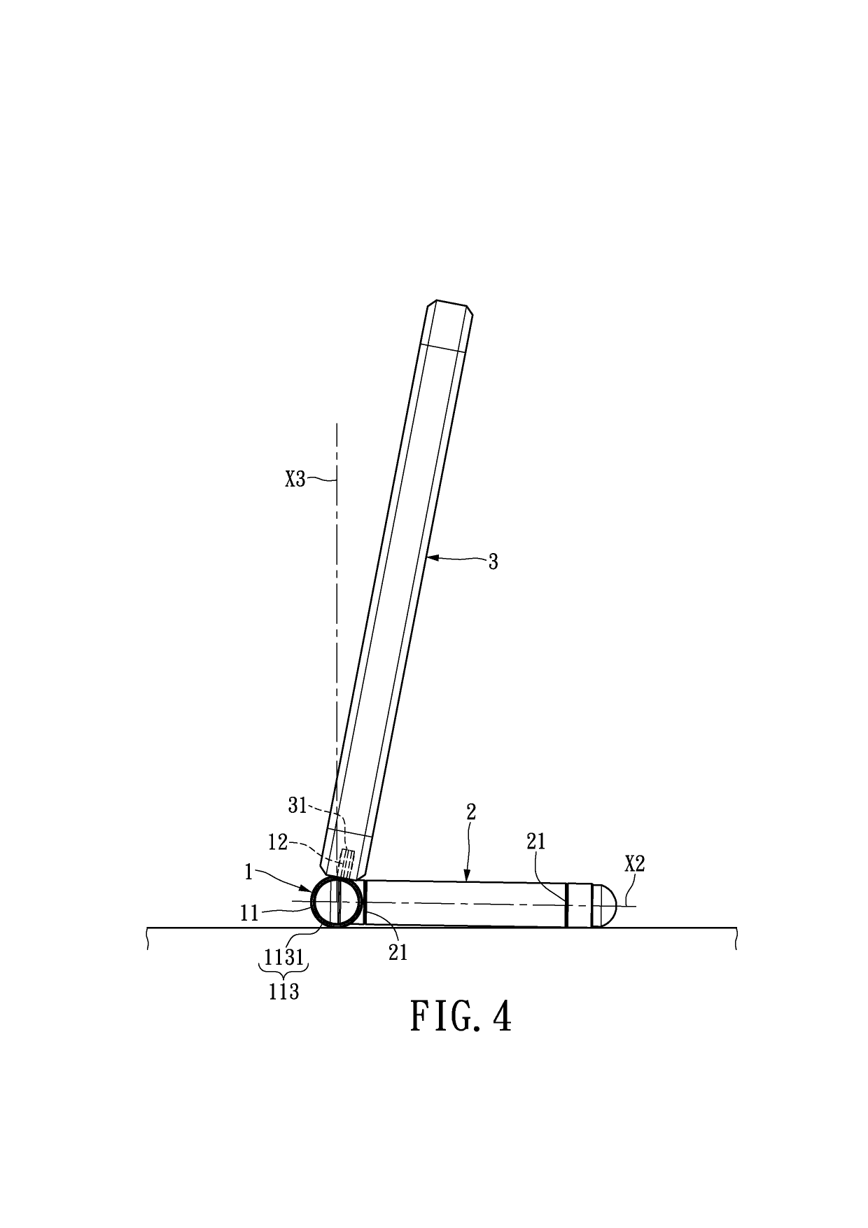

Please refer to FIGS. 3 and 4; the supporting stand 1 includes a tubular casing 11 and a positioning portion 12. The tubular casing 11 is formed as an open-end empty tube and a receiving compartment 111 is defined in the tubular casing 11. Moreover, a first guiding hole 112 (as shown in FIG. 2) is formed on the tubular casing 11 and communicates to the receiving compartment 111. In the embodiment, the tubular casing 11 is an empty circular cylinder. Alternatively, the tubular casing 11 may be an empty column body having a polygonal cross-section shape, but not restricted thereby. The positioning portion 12 is protruded from an outer surface of the tubular casing 11. In the embodiment, the positioning portion 12 is formed a flat protrusion which can be used to insert into the connection port 31 of the electronic device 3. The shape of the positioning portion 12 corresponds to that of the connection port 31; for example, the positioning portion 12 has a symmetric and irregularly-rectangular shape. A part of the outer surface of the tubular casing 11, which is in close to the positioning portion 12 may corresponds to the electronic device 3. For example, the outer surface of the tubular casing 11 has a planar portion located on two sides of the positioning portion 12 so that the side surface of the electronic device 3 may abut against the planar portion of the tubular casing 11. In other words, when the positioning portion 12 inserts into the connection port 31 of the electronic device 3, the side surface (e.g. the bottom surface) of the electronic device 3 is supported by the planar portion of the tubular casing 11. Accordingly, the electronic device 3 assembled with the portable supporting member can be firmly put on a working desktop, i.e., a table. On the other hand, the first guiding hole 112 is located on the tubular casing 11; in detail, the first guiding hole 112 is formed at a middle of the tubular casing 11, but not restricted thereby. The shape and the location of the first guiding hole 112 are not restricted by this embodiment.

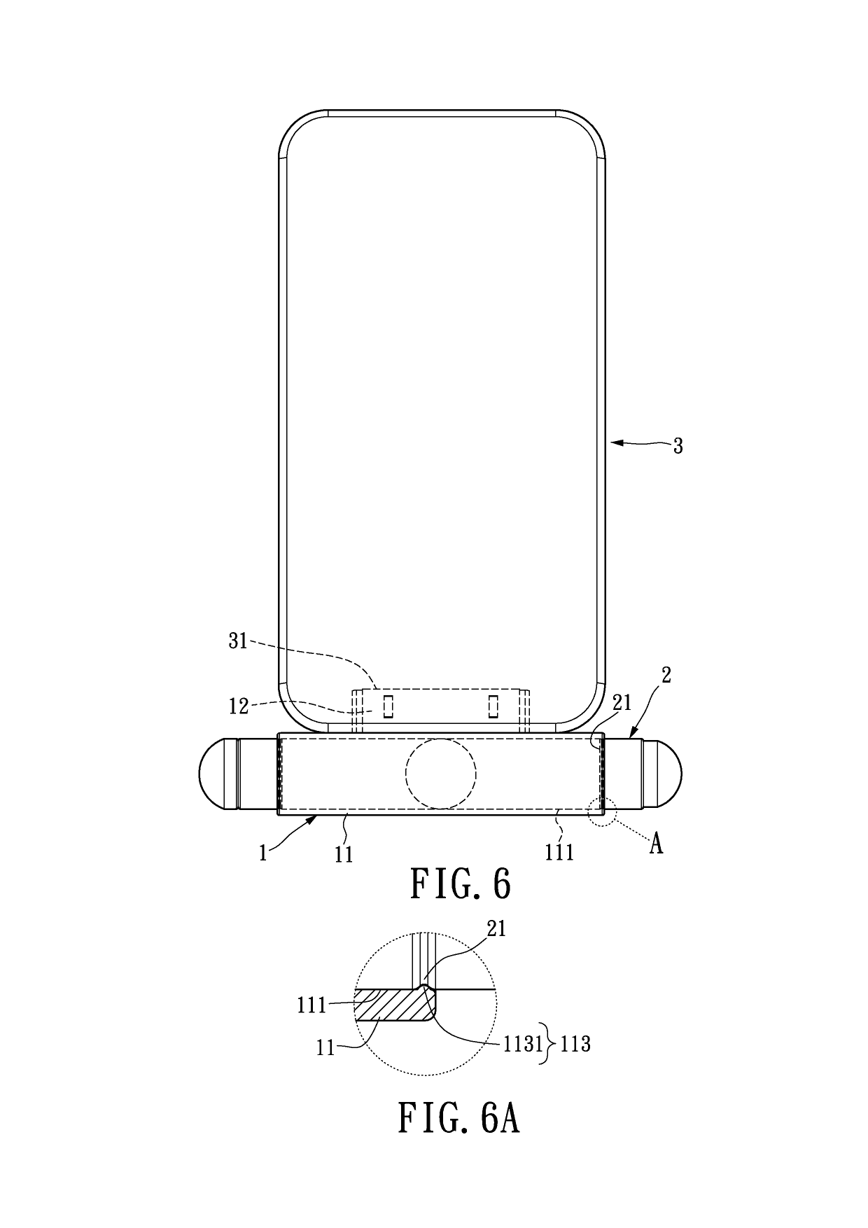

As shown in FIG. 1, the tubular casing 11 has two open ends and the tubular casing 11 has a locking portion 113 formed on each open end. In the structural detail, the locking portion 113 may be a convex protrusion 1131 as shown in FIG. 6. The locking portion 113 has a ring shape which is a convex ring body formed on the flange of the open end of the tubular casing 11, but not restricted thereby. In other words, the locking portion 113 may be formed and located on another portion of the tubular casing 11.

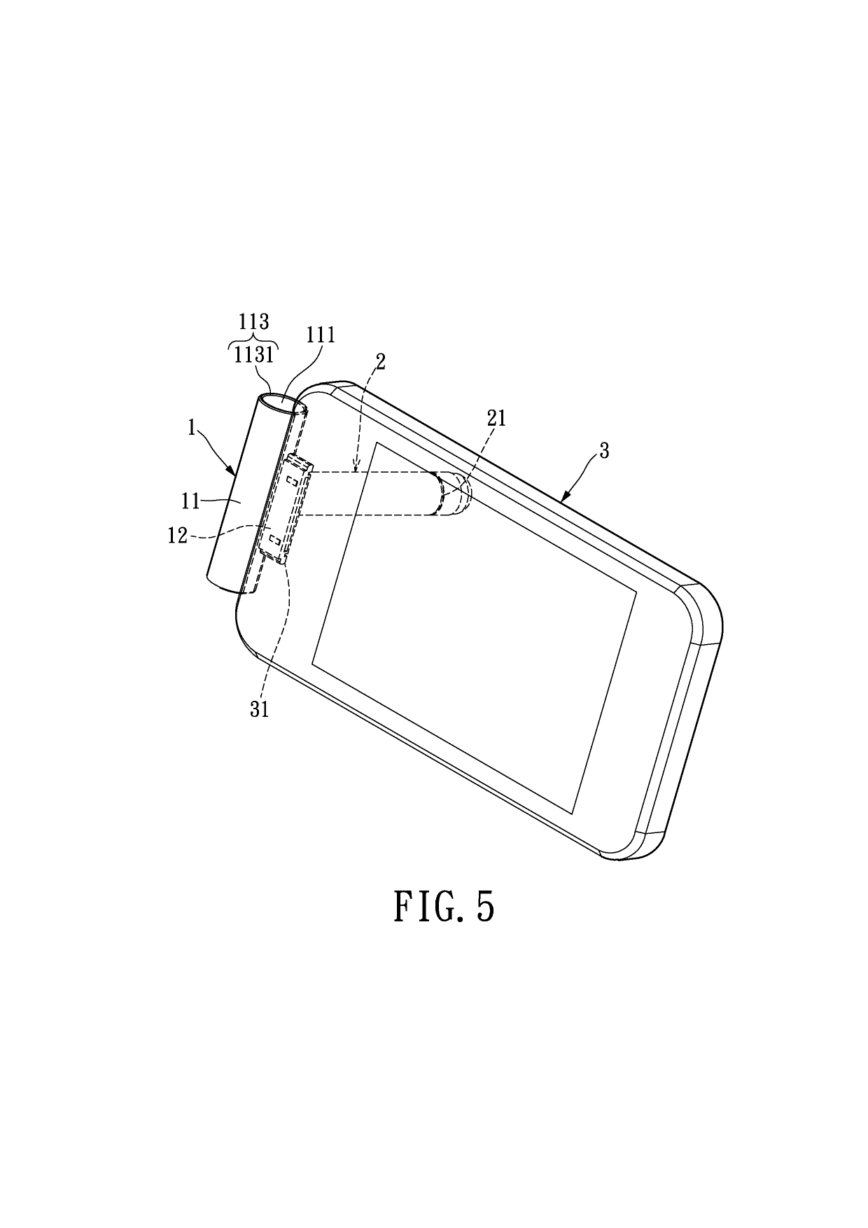

Please refer to FIGS. 5, 6 and 6A; the portable supporting member further has a rod body 2 that may be a pen or a stylus for a touch panel and the rod body 2 is selectively assembled with the supporting stand 1 in a first and a second positions. The rod body 2 has at least one anti-slip groove 21 formed thereon, which corresponds to the locking portion 113 of the tubular casing 11. In this exemplary embodiment, the rod body 2 has two anti-slip grooves 21 corresponding to the two locking portions 113. Each anti-slip groove 21 is a ring-shaped groove, but not restricted thereby. With regard to the second position, the rod body 2, as shown in FIGS. 6 and 6A, is penetrated through and received in the tubular casing 11. The external diameter of the rod body 2 is substantially less than the internal diameter of the tubular casing 11 so that the rod body 2 may be inserted into the receiving compartment 111 through either of the two open ends of the tubular casing 11. When the rod body 2 is axially received in the tubular casing 11, the locking portion 113 engages with the corresponding anti-slip groove 21. In detail, the locking portion 113 contacts the outer surface of the rod body 2 when the rod body 2 slides along the axial direction of the tubular casing 11. When the locking portion 113 is locked to the corresponding anti-slip groove 21, the rod body 2 can be located inside the tubular casing 11.

With regard to the first position, the rod body 2, as shown in FIGS. 2, 4 and 5, is assembled to the first guiding hole 112. The external diameter of the rod body 2 is substantially less than the diameter of the first guiding hole 112 so that the rod body 2 may be inserted into the first guiding hole 112. One end of the rod body 2 penetrates through the first guiding hole 112 until the inserted end of the rod body 2 abuts against the inner surface of the tubular casing 11. On the other hand, the outer surface of the rod body 2 contacts the side flange of the first guiding hole 112. The rod body 2 assembled with the supporting stand 1 in the first position can be used to support the electronic device 3 and the electronic device 3 can be put on the table in various types. As shown in FIG. 3, the electronic device 3 with the portable supporting member stands in a portrait orientation and the electronic device 3 with the portable supporting member, as shown in FIG. 5, stands in a landscape orientation.

The second embodiment is described hereinafter.

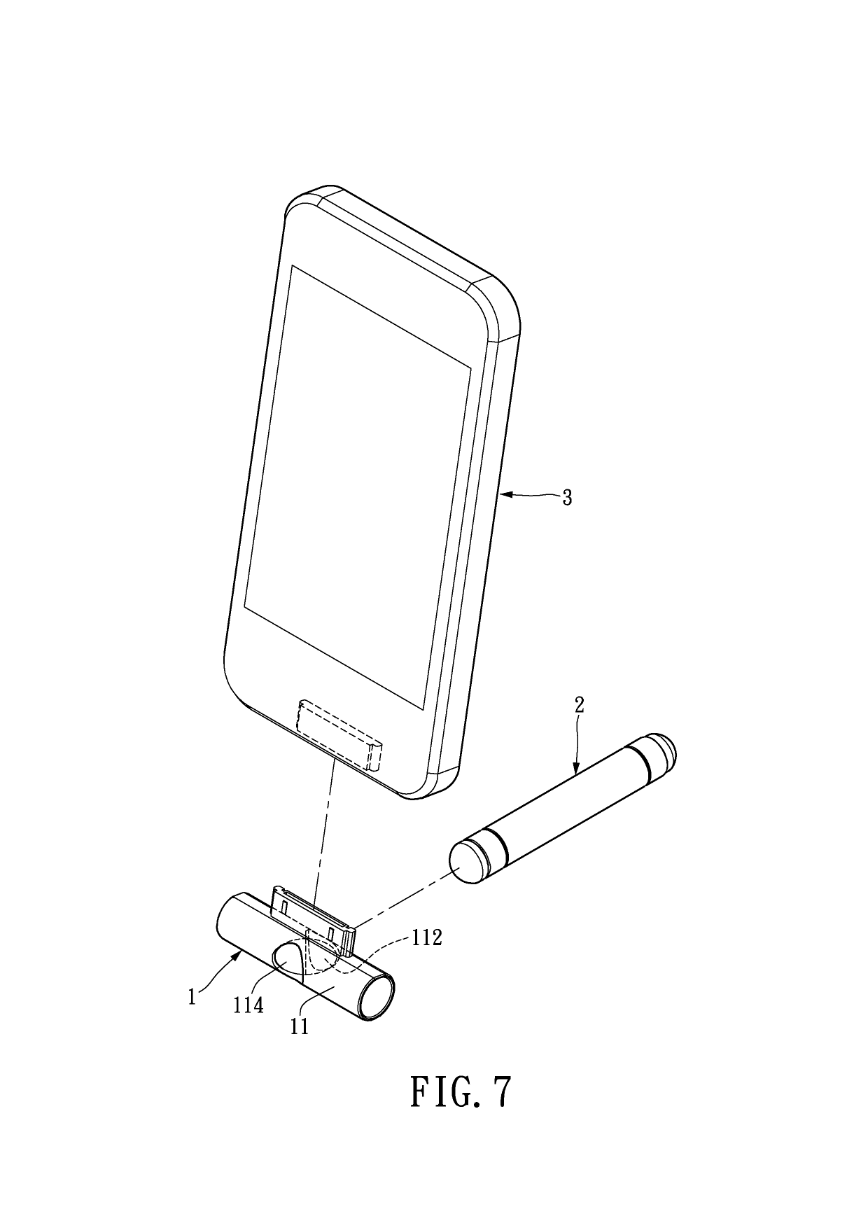

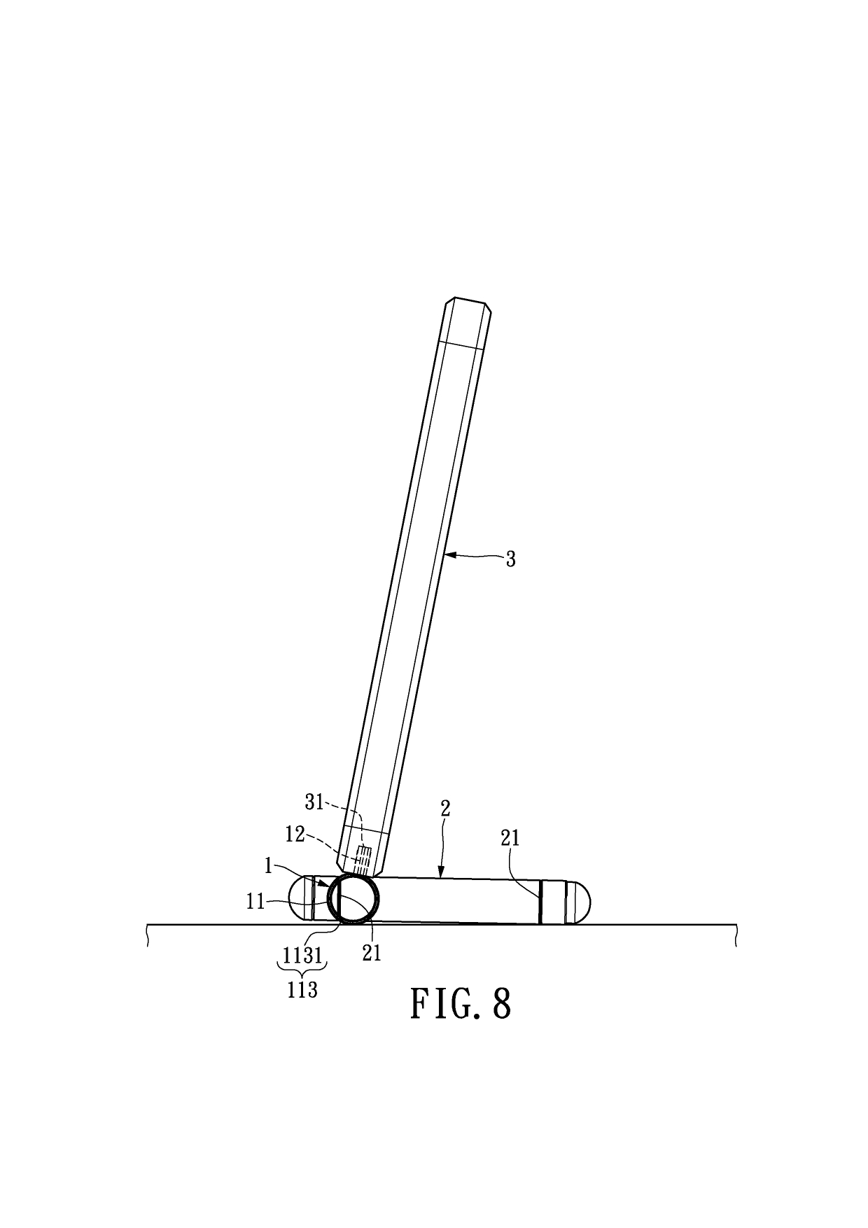

FIGS. 7 and 8 show the exploded views of the second embodiment of the present invention. In the second embodiment, the tubular casing 11 further has a second guiding hole 114 formed thereon.

In structural detail, the position of the second guiding hole 114 is opposite to the first guiding hole 112. The diameter of the second guiding hole 114 is substantially equal to that of the first guiding hole 112, but not restricted thereby.

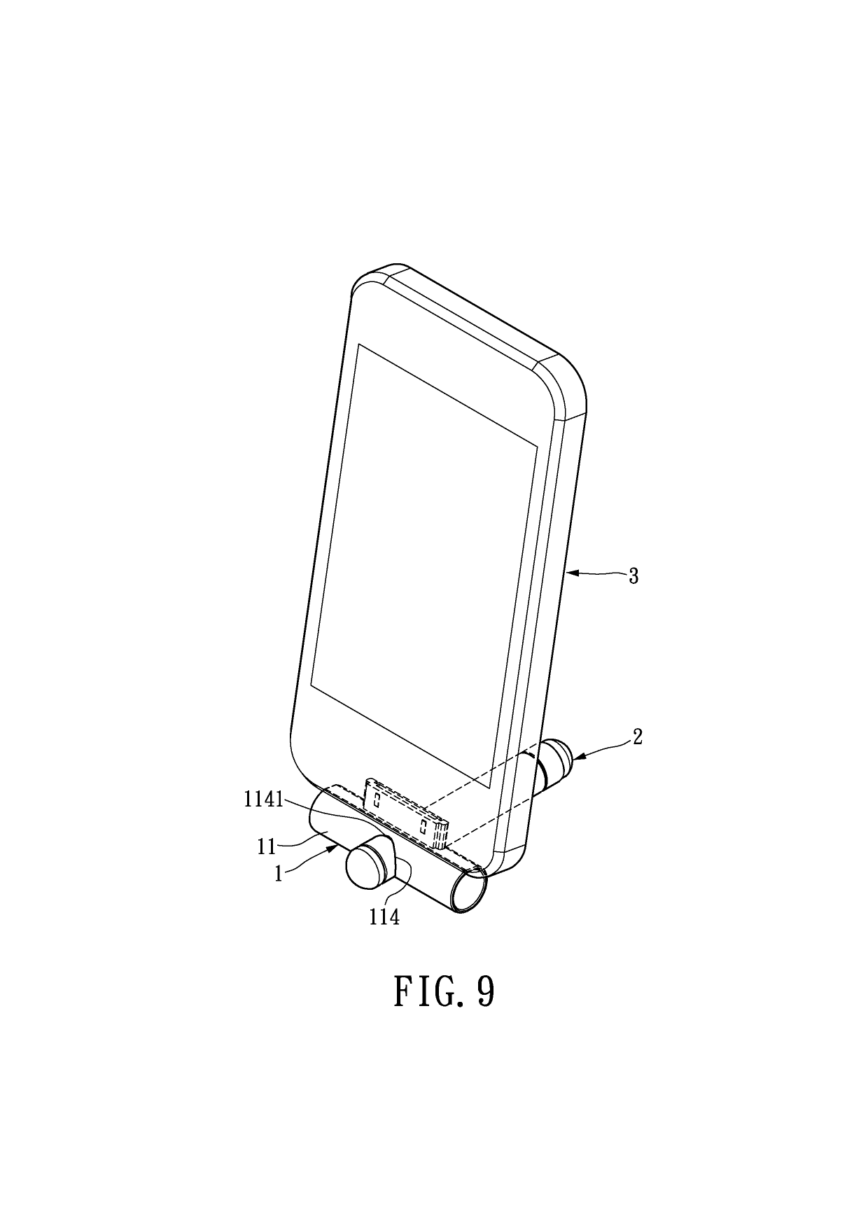

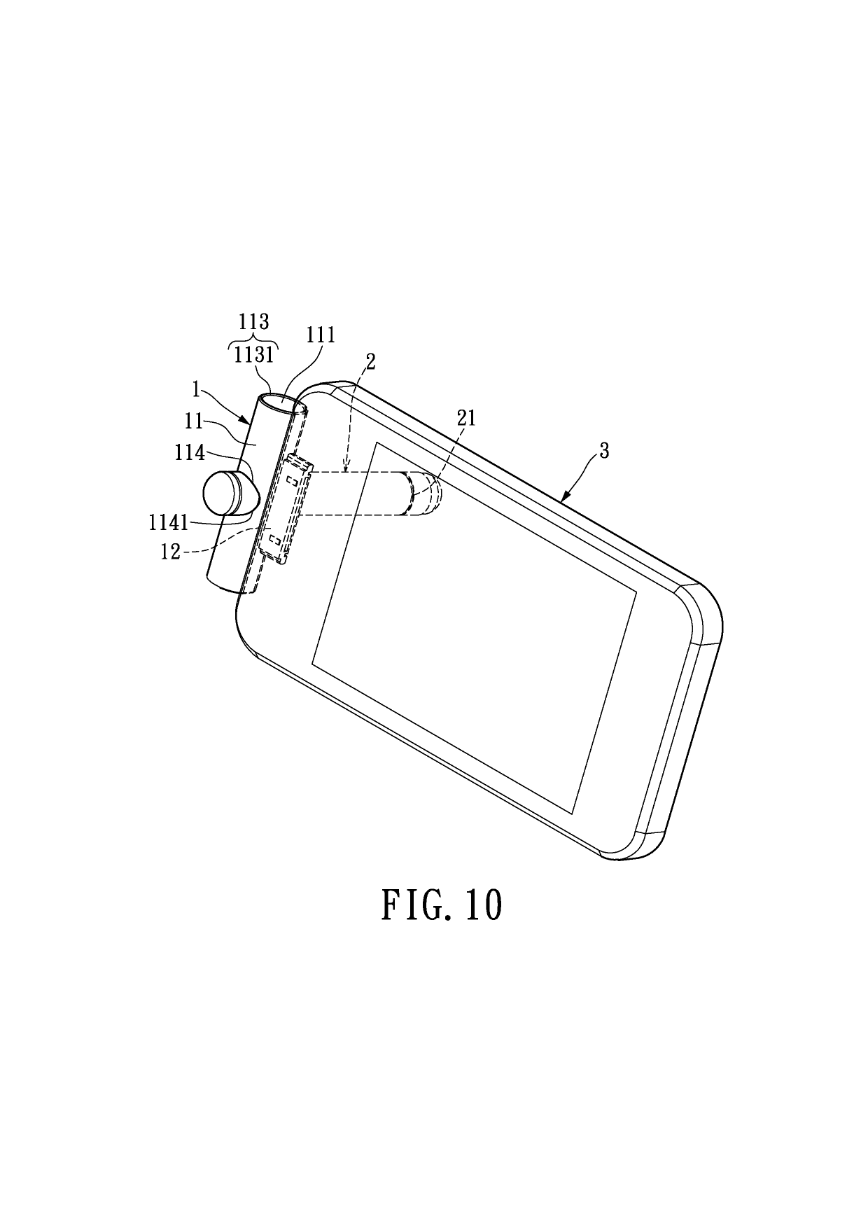

Please refer to FIGS. 9 and 10; one end of the rod body 2 penetrates through the first guiding hole 112 and the second guiding hole 114. When the rod body 2 is assembled to the supporting stand 1 in the first position, the outer surface of the rod body 2 contacts the side flange of the first guiding hole 112 and the side flange of the second guiding hole 114. Using the second guiding hole 114, the insertion of the rod body 2 penetrating through the first guiding hole 112 and the second guiding hole 114 provides improved supporting stability when the electronic device 3 stands in the portrait orientation.

Accordingly, the portable supporting member, which is formed by assembling the supporting stand 1 and the rod body 2, to support the electronic device 3. Therefore, the electronic device 3 may be stand in a portrait orientation or a landscape orientation for reading electronic book, watching video or playing electronic games.

Furthermore, by inserting the positioning portion 12 into the connection port 31 of the electronic device 3, the electrical components of the electronic device 3 is protected due to anti-dust and water-resistance provided by the positioning portion 12. In addition, the rod body 2 that may be a pen or a stylus can be inserted and received in the receiving compartment 111 of the tubular casing 11.

The description above only illustrates specific embodiments and examples of the present invention. The present invention should therefore cover various modifications and variations made to the herein-described structure and operations of the present invention, provided they fall within the scope of the present invention as defined in the following appended claims.

1. A portable supporting member connecting to a connection port of an mobile communication device, the portable supporting member comprising:
a supporting stand including:
a tubular casing having a receiving compartment formed therein along an elongated direction of the tubular casing defining a first axis and a first guiding hole formed on an outer surface of the tubular casing communicating to the receiving compartment; and
a positioning portion longitudinally arranged along the elongated direction of the tubular casing and protruded from an outer surface of the tubular casing, wherein the positioning portion is for inserting into the connection port of the mobile communication device;
a stylus pen selectively assembled with the tubular casing in a first and a second positions;
wherein as the stylus pen is assembled to the first guiding hole in the first position, defining a second axis along an elongated direction of the stylus pen, the stylus pen is intersected with the tubular casing to from an intersected supporting structure in a coplanar manner;
wherein the tubular casing and the stylus pen constitute coplanarity upon the first and second axes;
wherein the positioning portion protrudes from the surface of the tubular casing approximate to the first guiding hole; the positioning portion is non-coplanar from the coplanarity upon the first and second axis; and the positioning portion inclines toward the stylus pen;
wherein the rod body is penetrated through and received in the tubular casing in the second position.

2. The portable supporting member as claimed in claim 1, wherein the stylus pen has at least one anti-slip groove, the supporting stand has at least one locking portion corresponding to the anti-slip groove, the locking portion is protruded on the tubular casing, and when the stylus pen is received in the tubular casing, the locking portion engages with the anti-slip groove.

3. The portable supporting member as claimed in claim 2, wherein the tubular casing has two ends, and each of the two ends has one the locking portion.

4. The portable supporting member as claimed in claim 3, wherein the stylus pen has two the anti-slip grooves concavely formed on the outer surface thereof, the locking portion is a convex protrusion engaged to the corresponding anti-slip groove.

5. The portable supporting member as claimed in claim 1, wherein when the stylus pen is assembled to the first guiding hole, the outer surface of the stylus pen contacts the side flange of the first guiding hole, and one end of the stylus pen is located inside the receiving compartment and abuts against the inner surface of the tubular casing.

6. The portable supporting member as claimed in claim 1, wherein the supporting stand further has a second guiding hole formed on the tubular casing, the first and the second guiding holes are opposite to each other, and when the stylus pen is assembled to the first and the second guiding holes, the outer surface of the stylus pen contacts the side flange of the first guiding hole and the side flange of the second guiding hole.

7. (canceled)

8. (canceled)

9. (canceled)

10. (canceled)
